(19) United States
(12) Patent Application Publication
(10) Pub. No.: US 2026/0122845 A1
(43) Pub. Date: Apr. 30, 2026

(54) DRIVE BAY RADIATOR MODULE

(71) Applicant: HEWLETT PACKARD ENTERPRISE DEVELOPMENT LP, Spring, TX (US)

(72) Inventors: I-CHE TSAI, Taipei City (TW); An-Ching Wang, Taoyuan City (TW); Shou-Jen Yang, New Taipei City (TW)

(21) Appl. No.: 18/930,255

(22) Filed: Oct. 29, 2024

(51) Int. Cl. H05K 7/20

(52) U.S. Cl. CPC H05K 7/20272; H05K 7/20254; H05K 7/20263; H05K 7/20772

(57) ABSTRACT

A drive-bay radiator module has a form factor configured to be insertable into a drive bay of an information processing device, the drive bay being one of a set of drive bays each configured to receive a pluggable storage drive. The drive-bay radiator module includes a radiator which has an inlet liquid connector and an outlet liquid connectors. The module includes engagement features which are complementary to engagement features of the drive bays. The inlet liquid connector and the outlet liquid connector are configured to mate with liquid connectors in the drive bay, thus fluidically connecting the drive-bay radiator module with a liquid cooling loop of the system. The drive-bay radiator module may thus supplement the cooling capacity of a primary radiator installed in the liquid cooling loop within the system.

### INTRODUCTION

Information processing systems, such as servers, often need active cooling systems to ensure that they stay within desired operating temperatures. Air cooling systems use fans to flow air through a server to remove heat from components. However, in some cases, it may be desired to provide high powered components (e.g., CPUs) with even more cooling (or more efficient cooling) than would be feasible with air cooling alone, and thus in some cases liquid cooling systems may be utilized to supplement, or replace entirely, the air-cooling systems.

Specifically, in one liquid cooling approach, sometimes referred to as closed-loop liquid cooling, a server may have its own individual liquid coolant loop which is confined within that individual server. This liquid cooling loop is thermally coupled with the high-power heat generating components of the server, such as the CPUs, to provide extra cooling capacity. Specifically, the air-cooled heat sinks which would have been used to cool these components in an air-cooled system may instead be replaced by cold plates, which thermally couple the CPUs (or other components) to the liquid cooling loop. Thus, heat can be transferred from the high-power components into the liquid coolant. The heated liquid is then passed through a liquid-to-air heat exchanger, also known as a radiator, which extracts the heat from (i.e., cools) the liquid coolant. The cooled liquid is then circulated through the loop again to remove even more heat.

With a closed-loop liquid cooling approach, the server also has a group of fans, just like in an air-cooled system. The airflows generated by the fans can be used to cool lower-power components of the system which are not directly coupled to the liquid cooling loop, such as the motherboard, power supply units, and various peripherals (e.g., pluggable storage drives, etc.). In addition, the airflows are directed through the radiator to remove the heat from the liquid coolant.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a block diagram illustrating an example server.

FIG. 2 is a top view of another example server.

FIG. 3 is a front view of the server of FIG. 2.

FIG. 4 is a front view of a drive bay radiator module usable in the server of FIG. 2.

FIG. 5 is a side view of the drive bay radiator module of FIG. 4.

FIG. 6 is a perspective view of a drive cage of the server of FIG. 2.

### DETAILED DESCRIPTION

In a server which utilizes closed-loop liquid cooling, the radiator and the liquid conduits (tubes/pipes) which distribute the liquid can take up significant space. An air-cooled server does not require these components, and thus the closed-loop liquid cooled server will be more space constrained than a similar air-cooled server, all other things being equal. Accordingly, it can be challenging to find space to arrange all of the components in a closed-loop liquid cooled server. One place where a radiator is sometimes arranged in a server is between the front drive cages (disposed at a front panel) and the fans of the system.

As mentioned above, in close-loop systems the liquid cooling loop is often used to cool the CPUs of the server, while the remaining components are cooled directly by airflows. However, some systems include expansion modules (also sometimes called expansion cards), and such as graphics processing units (GPUs), and some of these expansion modules are becoming increasingly more powerful and generating more heat, to the point that it is expected that air cooling will soon be insufficient for some of these expansion cards. Thus, to allow these powerful cards to be cooled, liquid cold plates are now being integrated into some expansion cards.

To cool these liquid coolable expansion cards, one approach being considered is to connect the cold plates of the expansion cards into the same close-loop cooling system that is used to cool the CPUs in the server. However, one challenge with doing this is that the increased heat load generated by the expansion card may exceed the capacity of the radiator. Generally, the amount of heat that a radiator can dissipate into the air per unit of time depends upon its size, as the more surface area the radiator has over which the air can flow, the faster heat can be exchanged with the air. But in many systems, the radiator only has enough capacity to accommodate the heat load of the CPUs of the server and will not be able to handle the added heat load from the expansion card. Moreover, it might not be possible to expand the capacity of the radiator by using a larger version, as there is likely no free space to do so (closed loop liquid cooled systems are already very space constrained, as explained previously). Thus, providing sufficient radiator cooling capacity for both the CPUs of the system and for the expansion cards can be very challenging in a close-loop system.

To address these and other issues, examples disclosed herein provide servers with modular drive-bay radiators which can be installed within the drive bays of the drive cages of the server. Each drive bay radiator includes a radiator having a modular form factor compatible with installation in one of the drive cages. One or more of the drive bays may be plumbed with liquid connectors arranged to establish a liquid connection with a drive bay radiator installed in the drive bay, and these liquid connectors may integrate the drive bay radiator into a larger liquid cooling loop of the server. The liquid cooling loop may include a primary radiator, which may be installed, for example, between the fans and the drive cages in the usual fashion. The drive bay radiators may add their cooling capacity to that of the primary radiator, allowing for more heat to be removed from the liquid coolant per unit of time, all other things being equal. This additional cooling capacity may allow for the addition of hotter components, such as a liquid cooled expansion card, which might otherwise have exceeded the cooling capacity of the system.

The effect of adding the drive cage radiator may be similar to expanding the size of the primary radiator, but beneficially this effect is achieved without taking up any of the limited and valuable space in the middle region of the chassis where the primary radiator is traditionally disposed. Instead, the addition of the drive bay radiators takes up space only in the drive cages. These drive cages would usually be occupied with storage drives. But some systems do not necessarily need all of the storage capacity which the drive cages can accommodate, and for these systems it may be acceptable (even desirable, in some cases) to sacrifice some storage capacity in order to increase cooling capacity by replacing some storage drives with drive bay radiators.

Because the drive bay radiators are modular and can fit in existing drive cages commonly used in many chassis, a custom chassis to accommodate the radiators does not need to be designed. Thus, the same chassis design might be shared among multiple system configurations, which can greatly reduce costs (using custom chassis for different system configurations increases development, manufacturing, and logistical costs, as time needs to be spent designing each chassis, different tooling and/or manufacturing lines may be needed for each chassis, and different SKU or parts numbers may be needed for each chassis). Moreover, retrofitting of existing systems in the field to increase their cooling capacity may be possible, as the drive bay radiators may be installable in those existing systems without needing to change the chassis.

Furthermore, the modular nature of the drive bay radiators can allow for the cooling capacity of the system to be tuned to match the needs of the system by selectively varying the number of drive bay radiators that are used. For example, if more cooling capacity is needed, then more drive bay radiators can be installed in drive bays, whereas is less cooling capacity is needed then some drive bay radiators can be removed. In this manner, an optimal number of drive bay radiators can be found which provides adequate cooling without wasting valuable space by oversupplying more radiator capacity than is actually needed.

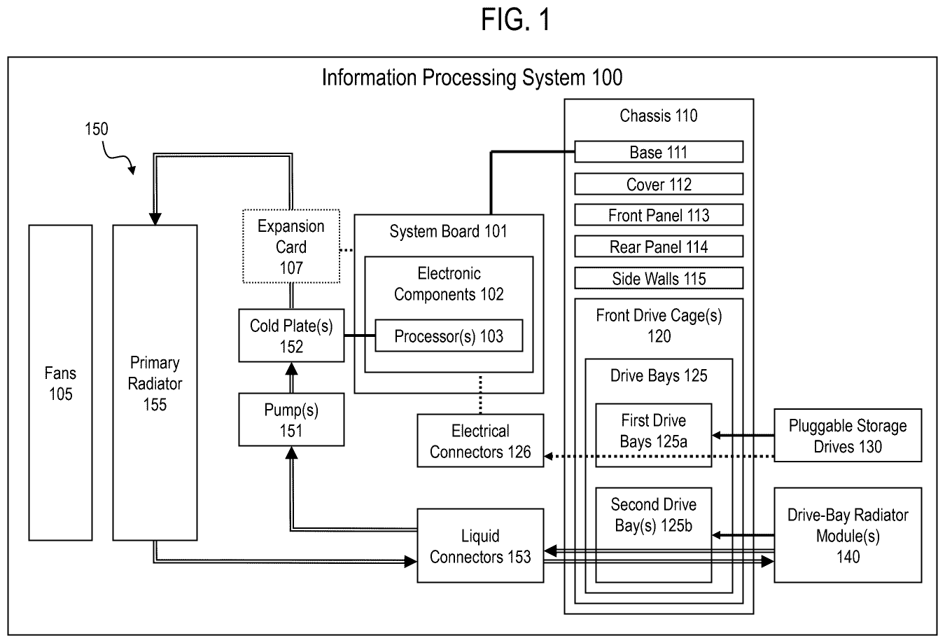

These and other examples will be described in greater detail below in relation to FIGS. 1-6.

FIG. 1 illustrates an example information processing system 100. FIG. 1 is schematic in nature and is not intended to illustrate shapes, sizes, spatial relationships, or other structural details accurately or to scale, unless otherwise noted herein. Components which are not illustrated in FIG. 1 may also be included in some examples disclosed herein, or one or more components illustrated in FIG. 1 may be omitted from some examples disclosed herein. In FIG. 1, solid lines extending between blocks indicate attachment/coupling between the components represented by the blocks, dashed lines extending between blocks indicate electrical connections between the components represented by the blocks, and double-solid lines extending between blocks indicate liquid connections between the components represented by the blocks.

The information processing system 100 may be, for example, a server. As shown in FIG. 1, the server 100 comprises a system board 101, fans 105, a chassis 110, pluggable storage drives 130, a liquid cooling loop 150, and one or more drive-bay radiators 140. In some examples, the system 100 may also, optionally, include one or more expansion modules 107 (also called expansion cards 107). These will be described in greater detail in turn below.

The system board 101 may be a motherboard, host-processor module (HPM), or other system board. The system board 101 comprises a printed circuit board (PCB) and various electronic components 102 mounted to the PCB. The electronic components 102 include at least one or more processor(s) 103. The electronic components 102 may also include memory modules, voltage regulators, and/or other components as would be familiar to those of ordinary skill in the art.

The chassis 110 comprises an enclosure which houses and supports the system board 101, fans, liquid cooling loop 150, and other components of the system 100, as well as various internal support structures to support those components. For example, the chassis 110 is formed from a base 121, a front panel 123, a rear panel 124, a top cover 122, and two side walls 125, which together form a housing/enclosure of the system 100, as is familiar to those of ordinary skill in the art. The front panel 123, rear panel 124, and side walls 125 are all perpendicular to the base 121. The top cover 122 is parallel to the base 121 and may be fully or partially removable or openable to allow access to the interior of the chassis 120. The front panel 123 and rear panel 124 are disposed opposite one another, with the two side walls 125 being perpendicular to and extending between the front panel 123 and the rear panel 124. The front panel 123 and the rear panel 124 may include airflow openings to allow airflow through the chassis, as well as electrical connectors or other ports. In addition, various bays may be provided at the front panel 123 and/or the rear panel 124 to allow for the removable installation of removable modules in the system, such as storage drives and PSUs. In some cases, portions of these removable modules may become part of the front panel 123 or the rear panel 124 when installed in the system (i.e., neither the front panel 123 nor the rear panel 124 is necessarily formed from a single monolithic structure).

In addition, the chassis 120 includes one or more front drive cages 120. These front drive 120 cages are disposed at, and may form part of, the front panel 113 of the chassis 110. Each front drive cage 120 includes walls and/or other support structures which define a number of drive bays 125 inside the drive cage 120. Each drive bay 125 includes a volume in which a pluggable storage drive 130 can be inserted, together with portions of the drive cage 120 which bound and define that volume. Each bay 125 also includes engagement structures (e.g., rails) which engage with the pluggable module to guide the module into an installed position and to support the module once installed.

The drive bays 125 may include two types of drive bays, a first drive bay 125a and a second drive bay 125b. These may differ from one another in which type of module they are configured to receive, with the first drive bays 125a being configured to receive a pluggable storage drive 130 and the second dive bays 125b being configured to receive a drive-bay radiator module 140. More specifically, the second drive bays 125b may have drive bay liquid connectors 153 disposed therein, or adjacent thereto, whereas the first drive bays 125b may lack such liquid connectors 153. The liquid connectors 153 are configured to engage and fluidically connect with a drive bay radiator module 140 when one is installed in the corresponding second drive bay 125b. The first drive bays 125a instead may have electrical connectors 126 disposed therein, or adjacent thereto, which engage and electrically connect with a pluggable storage drive 130 when one is installed in the corresponding first drive bay 125a. In some examples, the second drive bays 125b may also include similar electrical connectors, allowing the second drive bays 125b to interchangeably receive either a drive-bay radiator module 140 or a storage drive 130. In other examples, the second drive bays 125b may exclude electrical connectors. In some examples, all of the drive bays 125 are second drive bays 125b.

In some examples, the first drive bays 125a and the second drive bays 125b may have the same shape/size and the same engagement features as one another. Thus, the drives 130 which are installable in the drive bays 125a may have similar form factors as the drive-bay radiator modules 140 installable in the drive bays 125b. Accordingly, the pluggable storage drives 130s may physically fit within the second drive bays 125b (although the drive 130 might not be functional in the second bays 125b, if that bays 125b lack electrical connectors 126). Similarly, the drive bay-radiator modules 140 may physically fit within the first drive bays 125a (although the module 140 would not be functional in the first bays 125a because they lacks liquid connectors 153).

In some examples, a first drive bay 125a can be converted into a second drive bay 125b by adding the liquid connectors 153 to that bay 125. In some examples, an electrical connector 126 of a first drive bay 125a is attached to a backplane, which is coupled to a rear of a drive cage 120. In some examples, converting a first drive bay 125a into a second drive bay 125b may include positioning the liquid connectors 153 at or in an aperture through the backplane. In other examples, in which the backplane lacks the aperture, the backplane may need to be removed or replaced with a new backplane that has the aperture in order to form the drive bay 125b.

As noted above, each drive bay radiator module 140 is configured to be installed in one or more second drive bays 125b. In some examples, a single drive bay radiator module 140 is configured to be installed in a single drive bay 125b. In other examples, a single drive bay radiator module 140 is configured to span a group of multiple contiguously adjacent drive bays 125b.

Each drive bay radiator module 140 includes a radiator having an inlet liquid connector, an outlet liquid connector, a liquid conduit extending between the connectors, and fins thermally coupled to the liquid conduit. The inlet and outlet liquid connectors are arranged to mate with the liquid connectors 153 of a second drive bay 125b when the drive bay radiator module 140 is installed in that drive bay 125b, thereby fluidically connecting the module 140 to the liquid cooling loop 150. Thus, liquid coolant from the loop 150 can flow through the liquid conduit of the module 140, and heat carried thereby can be transferred into the fins which are thermally coupled to the conduit. Air then flows through the fins, allowing the heat to be transferred from the fins into the air. In this manner, the air flowing through the radiator cools the liquid coolant.

In addition to the radiator, the radiator module 140 may include a housing to hold the radiator as well as engagement features configured to engage with the engagement features of the second drive bay 125b. The engagement features of the drive bay radiator module 140 are complementary to the engagement features of the second drive bay 125b. Moreover, in some examples, the engagement features of the second drive bay 125b are the same as the engagement feature of the first drive bay 125a, and thus in some examples, the engagement features of the drive bay module 140 may mimic those of the pluggable storage drives 130.

In some examples, the drive bay radiator module 140 is configured to be pluggable. This means that the module 140 is designed to be plugged into or removed from the second drive bay 125b repeatedly and relatively easily (i.e., without requiring the use of tools or the opening/disassembly of the chassis 110). In some of these examples, the liquid connectors 153 and the corresponding liquid connectors of the radiator module 140 may be quick-disconnect (QD) liquid connectors which can allow for such easy and repeatable coupling and decoupling. In addition, in such examples, the radiator module 140 may include user actuatable latches and/or installation/removal levers similar to those carried by storage drives 130 to secure the module 140 in the installed position and to create a mechanical advantage to assist in installation or removal.

In other examples, the drive bay radiator module 140 is configured to be more permanently installed, meaning that while removal may be possible it will generally be a more involved process, often requiring the use of tools and/or the opening or disassembly of the chassis 110. In some of these examples, the liquid connectors 153 and the corresponding liquid connectors of the radiator module 140 may be hose-barb fittings, brazed fittings, compressing fittings, threaded fittings, or other liquid fittings. In addition, in such examples, the radiator module 140 may omit manually actuatable latches and instead rely on screws, rivets, or other more permanent fasteners to secure the drive bay radiator module 140 in the drive bay 125b.

The liquid cooling loop 150 comprises one or more pumps 151, one or more cold plates 152, a primary radiator 155, and the liquid connectors 153. The liquid cooling loop 150 also comprises liquid cooling infrastructure to fluidically connect the other components together, including hoses/tubes/pipes, fittings, manifolds, etc. The liquid cooling loop 150 may be filled with liquid coolant (e.g., water, propylene glycol and water (PGW), etc.).

The cold plates 152 may be thermally coupled with electronic components 102 which they are intended to cool, including, in some examples, the processor(s) 103. In some examples, a high powered expansion card, such as a GPU, may also have a cold plate 152 which is integrated into the liquid cooling loop 150. Although shown as conceptually separate, in some implementations the cold plates 152 and the pumps 151 may be physically packaged together as part of the same unit.

The primary radiator 155 comprises a standard radiator, which includes a liquid conduit and fins thermally coupled therewith. In some examples, the primary radiator 155 is disposed within a middle region of the chassis rearwards of the front drive cages 120—for example, between the front drive cages 120 and the system board 101. In some examples, the primary radiator extends across substantially the full width of the chassis 110, excluding gaps along the sides to allow for hose routing.

The pumps 151 create a pressure differential to drive the liquid coolant to flow through the loop 150. Specifically, as suggested by the arrows in the FIG. 1, liquid coolant may flow through the cold plates 152, extracting heat from the electronic components 102. This heated liquid may then flow through the primary radiator 155 and the drive bay radiator modules 140, wherein heat is removed from the liquid coolant by air driven to flow through the radiators 155/140 via the fans 105. The now-cooled liquid is then returned to the cold plates 152 to begin the process again. Note that the aforementioned flow path is an illustrative example only, and variations thereof may be used in various examples disclosed herein. For example, the drive bay radiator module 140 could be disposed upstream of the primary radiator in the flow path 155. As another example, the pumps 151 could be disposed downstream of the cold plates 152, or between two cold plates 152, or with one upstream of the cold plates and one downstream of the cold plates 152, or between the primary radiator 155 and the drive bay radiator modules 140, or anywhere else in the liquid cooling loop.

In some examples, optionally the system 100 may include one or more expansion modules 107. In the industry, expansion modules are also often called expansion cards, and this is true herein as well. However, the usage of this terminology is not intended to limit the form factor or structure of the module in any way—e.g., some expansion modules 107 which do not physically resemble a “card” may nonetheless be referred to as an expansion card 107. The expansion card may be, for example, a GPU, a network interface card (NIC), a host bus adapter (HBA), an optical transceiver, a hardware accelerator, or any other expansion card. In some examples, the expansion card 107 may be a liquid coolable device, meaning that it has a liquid cooled cold plate integrated therein, or is configured to receive or be thermally coupled to such a cold plate. Thus, the expansion card 107 may be integrated into the liquid cooling loop 150, with liquid coolant flowing through or past the cold plate of expansion card 107. In some examples, the cooling capacity of the primary radiator 155 may be sufficient to cool the processors 103, but may be insufficient to also cool the expansion card 107. In some examples, the one or more drive-bay radiator modules 140 may collectively supply sufficient additional cooling capacity to allow for the cooling of the expansion card 107—that is, the combined cooling capacity of the primary radiator 155 and the drive-bay radiator modules 140 may be sufficient to cool the processors 103 and the expansion cards 107. In some examples, if additional liquid cooled expansion cards 107, or if existing expansion cards 107 are replaced with newer liquid cooled expansion cards 107 which require more cooling, additional drive bay radiator modules 140 may be added to the system to increase the cooling capacity thereof as needed. In this manner, the modular nature of the drive bay radiator modules 140 may allow the cooling capacity of the system to be selectively scaled up (or down) to meet the changing needs of the system.

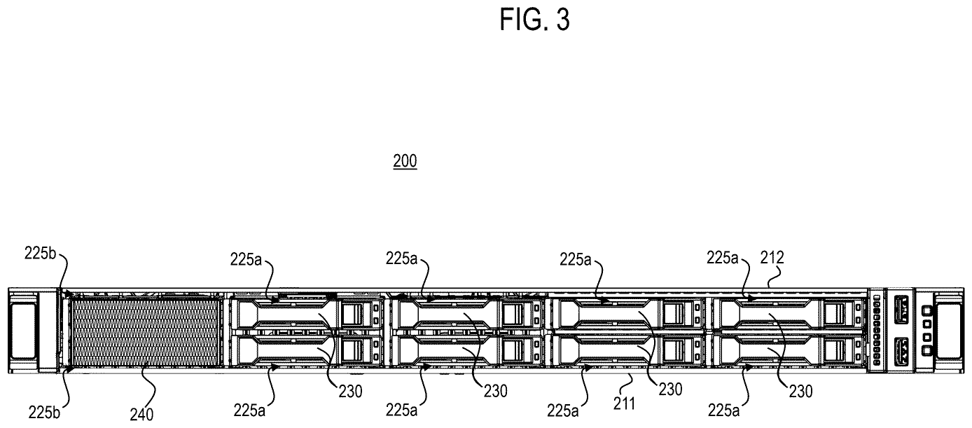

Turning now to FIGS. 3-6, an example system 200 will be described, as well as an example drive-bay radiator module 240 usable in the system 200. The system 200 is one example implementation of the system 100, and the drive-bay radiator module 240 is one example implementation of the of the drive-bay radiator module 140. In FIGS. 3-6, components of the system 200 and module 240 which correspond to (i.e., are example implementations of) components of the system 100 and module 140 will be given similar reference numbers having the same last two digits, such as 120 and 220. Descriptions of components of the system 100 and module 140 above also may apply to the corresponding components of the system 200 and module 240, and thus duplicative description of aspects already described above may be omitted below, with the description focusing on aspects of the system 200 which have not heretofore been described.

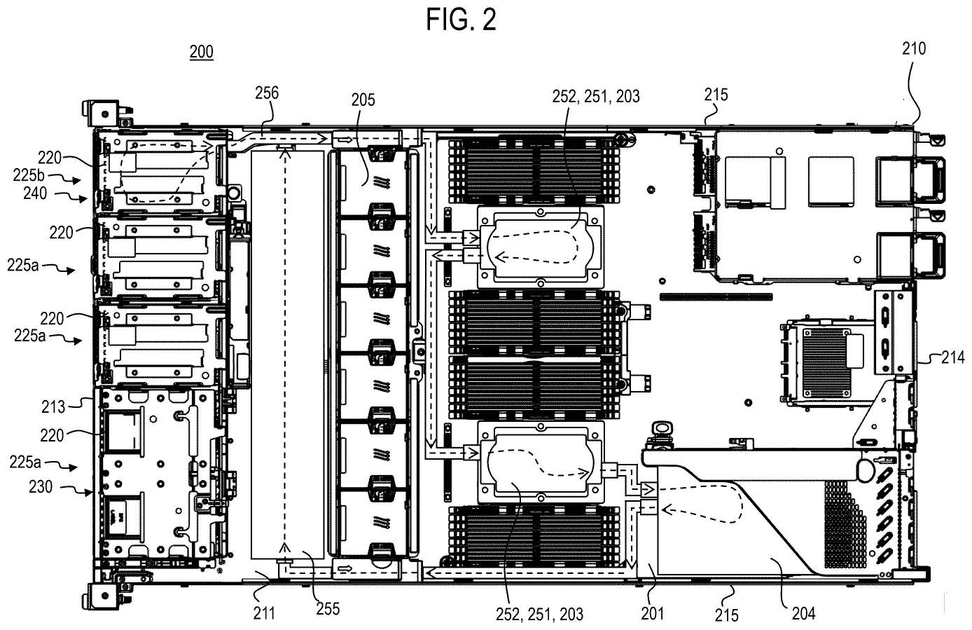

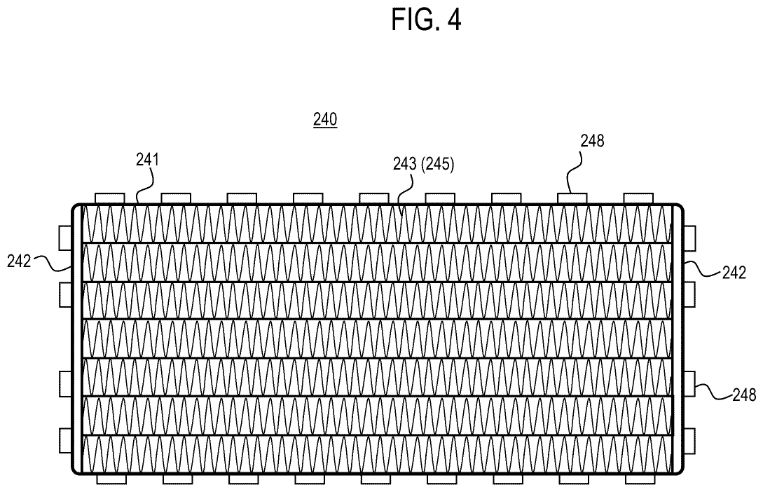

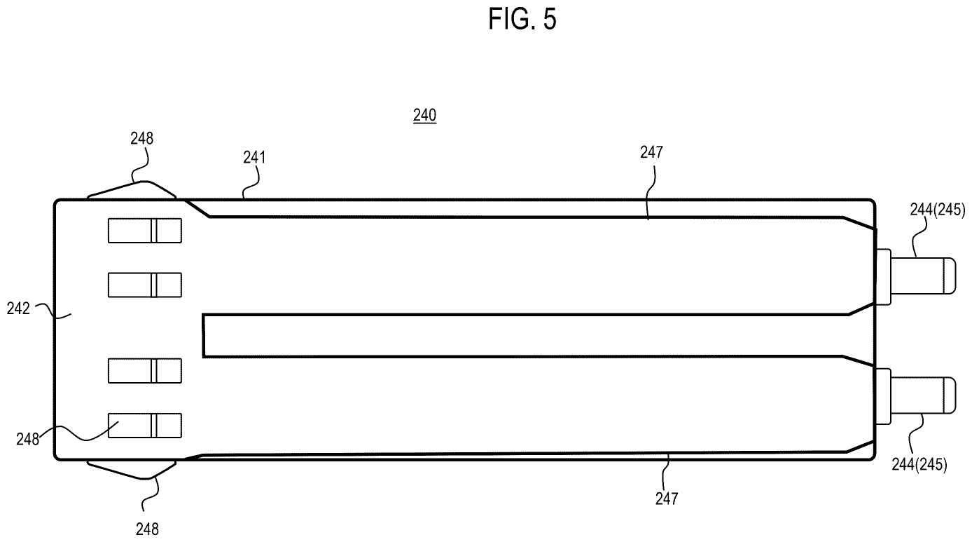

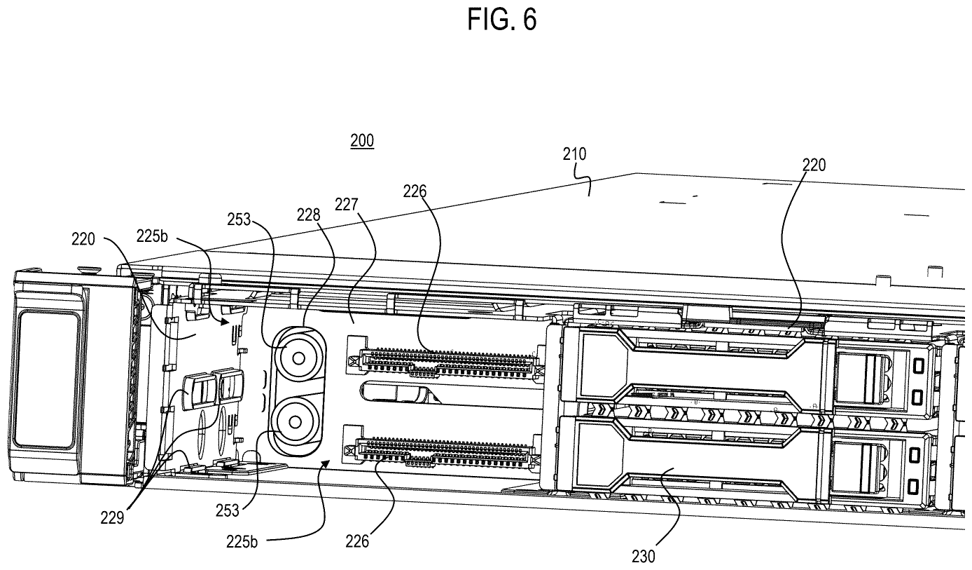

In this example, the system 200 is an 1U server, wherein 1U refers to the server being one standard “rack unit” (U) in height. FIGS. 2 and 3 show the system 200 in top and front views, while FIG. 6 shows a detail of some second bays 225b of the system 200 in perspective view. FIGS. 4 and 5 show front and side view of the module 240 in isolation.

As shown in FIG. 2, the server 200 comprises a system board 201, fans 205, a chassis 210, pluggable storage drives 230, a liquid cooling loop 250, and one or more drive-bay radiators 240. These will be described in greater detail in turn below.

The system board 201 may be a motherboard, host-processor module (HPM), or other system board. The system board 201 comprises a printed circuit board (PCB) and various electronic components 202 mounted to the PCB. The electronic components 202 include at least one or more processor(s) 203 and an expansion card 204. The electronic components 202 may also include memory modules, voltage regulators, and/or other components as would be familiar to those of ordinary skill in the art.

The chassis 210 comprises an enclosure which houses and supports the system board 201, fans, liquid cooling loop 250, and other components of the system 200, as well as various internal support structures to support those components. For example, the chassis 210 is formed from a base 221, a front panel 223, a rear panel 224, a top cover 222 (omitted from FIG. 2), and two side walls 225, which together form a housing/enclosure of the system 200, as is familiar to those of ordinary skill in the art.

In addition, the chassis 220 includes a number of front drive cages 220. These front drive 220 cages are disposed at, and may form part of, the front panel 213 of the chassis 210. Each front drive cage 220 includes walls and/or other support structures which define a number of drive bays 225 inside the drive cage 220. Each drive bay 225 includes a volume in which a pluggable storage drive 230 can be inserted, together with portions of the drive cage 220 which bound and define that volume. Each bay 225 also includes engagement structures 229 (see FIG. 6) which engage with the pluggable module to guide the module into an installed position and to support the module once installed.

The drive bays 225 include two types of drive bays, a first drive bay 225a and a second drive bay 225b. The first drive bays 225a are configured to receive a pluggable storage drive 230 and the second dive bays 225b being configured to receive a drive-bay radiator module 240, as shown in FIG. 3. More specifically, as shown in FIG. 6, the second drive bays 225b may have drive bay liquid connectors 253 disposed therein, or adjacent thereto, whereas the first drive bays 225b may lack such liquid connectors 253. The liquid connectors 253 are configured to engage and fluidically connect with a drive bay radiator module 240 when one is installed in the corresponding second drive bay 225b. Specifically, in this example, the drive bay radiator module 240 is configured to fill two adjacent drive bays 225b, and thus one set of liquid connectors 253 is provided for the two drive bays 225b, as show in FIG. 6. This set of liquid connectors 253 may be provided at/in an apertures 228 through a backplane 227. This backplane 227 may be attached to the rear of the drive cage 220 and may carry electrical connectors 226 for connecting with storage drives 230. The set of liquid connectors 253 may include an supply connector 253 to supply liquid to the module 240 and an return connector 253 to return liquid from the module 240. In the illustrated example, the liquid connectors 253 are quick-disconnect (QD) fitting, but in other examples other fittings could be used.

The first drive bays 225a may have electrical connectors 226 disposed therein, or adjacent thereto, which engage and electrically connect with a pluggable storage drive 230 when one is installed in the corresponding first drive bay 225a. In some examples, the second drive bays 225b may also include similar electrical connectors, allowing the second drive bays 225b to interchangeably receive either a drive-bay radiator module 240 or a storage drive 230.

As shown in FIG. 3, the first drive bays 225a and the second drive bays 225b may have the same shape/size and the same engagement features as one another. The drive-bay radiator modules 240, being configured to fill two bays 225b, may thus have a size and shape similar to two of the storage drives 230 stacked. In addition, as shown in FIG. 5, the drive bay radiator module 240 may have electromagnetic interference (EMI) shielding springs 248 arranged similar to the storage drives 230.

The drive bay radiator module 240 also comprises engagement features 247 arranged along the two sides thereof. These engagement features 247 comprise rail-like protrusions which have dimensions arranged so as to engage with the engagement features 229 of the bays 225b. This engagement guides the module 240 into an installed position in the bays 225b, aligning the liquid connectors 244 of the module 240 with the liquid connectors 253 in the bays 225b, in some cases allowing for blind-mating therebetween. The engagement between the engagement features 247 and engagement features 229 also supports the drive bay radiator module 240 within the bay 225b once installed.

As shown in FIGS. 4 and 5, the drive bay radiator module 240 includes a radiator 245 having an inlet liquid connector 244, an outlet liquid connector 244, a liquid conduit (not visible) extending between the connectors, and fins 243 thermally coupled to the liquid conduit. The inlet and outlet liquid connectors 244 are arranged to mate with the liquid connectors 253 of a second drive bay 225b when the drive bay radiator module 240 is installed in that drive bay 225b, thereby fluidically connecting the module 240 to the liquid cooling loop 250. Thus, liquid coolant from the loop 250 can flow through the liquid conduit of the module 240, and heat carried thereby can be transferred into the fins which are thermally coupled to the conduit. Air then flows through the fins 243, allowing the heat to be transferred from the fins 243 into the air. In this manner, the air flowing through the radiator 245 cools the liquid coolant.

In addition to the radiator, the radiator module 240 may include a housing 241 to hold the radiator as well as the engagement features 247 described above. The engagement features 247 may be provided as part of side panels 242, which are attached to two opposite sides of the housing 241. The side panels 242 and engagement features 247 thereof may be configured to allow the module 240 to engage with drive bays 225b which were originally designed to receive storage modules 230. In other words, aside from the provisioning of the liquid connectors 253, the drive bays 225b may be the same as the other drive bays 225a which are to receive modules 230.

Returning to FIG. 2, the liquid cooling loop 250 comprises one or more pumps 251, one or more cold plates 252, a primary radiator 255, and the liquid connectors 253. The liquid cooling loop 250 also comprises liquid cooling infrastructure to fluidically connect the other components together, including hoses 256, fittings, manifolds, etc. The liquid cooling loop 250 may be filled with liquid coolant (e.g., water, propylene glycol and water (PGW), etc.).

The cold plates 252 may be thermally coupled the processor(s) 203. In some examples, the expansion card 204 is also liquid cooled and thus has an integral cold plate 252 (not visible). In the illustrated implementation, the cold plates 252 and the pumps 251 may be physically packaged together as part of the same unit. In other words, there are two cold plate 252/pump 251 units in system 200, each disposed in thermal contact with one processor 203 of the system 200.

The primary radiator 255 comprises a standard radiator, which includes a liquid conduit and fins thermally coupled therewith. The primary radiator 255 is disposed within a middle region of the chassis rearwards of the front drive cages 220 and between the front drive cages 220 and the system board 201. As shown, the primary radiator extends across substantially the full width of the chassis 210, excluding gaps along the sides to allow for hose 256 routing.

The pumps 251 create a pressure differential to drive the liquid coolant to flow through the loop 250. Specifically, as suggested by the arrows in the FIG. 2, liquid coolant flow through the cold plates 252 and then through the expansion card 204, extracting heat from the processors 203 and expansion card 204. This heated liquid may then flow through the primary radiator 255 and then into the drive bay radiator modules 240 via a supply liquid conduit 253 in the drive bay 252b. Note that in FIG. 2 the tube 256 which connects the primary radiator 255 to the module 240 is only partially visible, as it may run below another tube 256. The primary radiator 255 and the drive-bay radiator module 240 both remove heat from the liquid coolant by air driven to flow through the radiators 255/240 via the fans 205. The now-cooled liquid is then returned from the module 240 to the cold plates 252 to begin the process again. Note that the aforementioned flow path is an illustrative example only, and variations thereof may be used in various examples disclosed herein.

In the illustrated example, only one drive-bay radiator module 240, which spans two bays 252b, is used. However, it should be understood that the same system 200 could be modified to use two, three, four, or five of the two-bay drive-bay radiator modules 240. This would involve disposing liquid connectors 253 within each of the drive cages 220 in an analogous fashion as is shown in FIG. 6. The supply liquid connectors 253 could all be coupled together forming a supply manifold, which could be arranged, for example, between the rear of the drive cages 220 and the front of the primary radiator 255. The return liquid connectors 253 could all be coupled together forming a return manifold, which similarly could be arranged, for example, between the rear of the drive cages 220 and the front of the primary radiator 255 (disposed either above or below the supply manifold).

It should be understood that the same system 200 could be modified to use single-bay drive-bay radiator modules which span a single bay 225b instead of the modules 240 which span two bays 225b. The single-bay drive bay radiator modules would be similar to the modules 240 except with a smaller form factor designed to fit one bay 225a. The liquid connectors 244 may also need to be rearranged accordingly, such as by being place horizontally adjacent, instead of vertically stacked.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An information processing system, comprising:
a chassis comprising a front drive cage comprising multiple drive bays; and
a system board supported by the chassis;
a liquid cooling loop comprising a primary radiator disposed in the chassis, one or more cold plates, and at least one set of drive bay liquid connectors each being disposed in one or more of the drive bays, the drive bay liquid connectors including at least a first set of drive bay liquid connectors;
a drive bay radiator module disposed in a first drive bay of the drive bays and fluidically connected to the liquid cooling loop by the first set of drive bay liquid connectors.

2. The information processing system of claim 1,
wherein the drive bay radiator module is contained entirely within the first drive bay.

3. The information processing system of claim 1,
wherein the drive bay radiator module spans the first drive bay and an adjacent second drive bay of the drive bays.

4. The information processing system of claim 1,
wherein each of the drive bays comprises engagement features configured to removably engage with a pluggable storage drive on condition of the pluggable storage drive being installed in the drive bay; and
the drive bay radiator module comprises engagement features complementary to the engagement features of the drive bays, the engagement features of the drive bay radiator module being engaged with the engagement features of the first drive bay to support the drive bay radiator module.

5. The information processing system of claim 1,
wherein the drive bay liquid connectors comprise quick disconnect (QD) fittings.

6. The information processing system of claim 1,
further comprising a set of fans;
wherein the primary radiator is disposed between the set of fans and the front drive cage.

7. The information processing system of claim 1,
further comprising an expansion module thermally coupled to one of the cold plates.

8. The information processing system of claim 7,
wherein the system board comprises one or more processors, each thermally coupled with a corresponding one of the cold plates; and
wherein a cooling capacity of the primary radiator is sufficient to cool the one or more processors but insufficient to cool the one or more processors together with the expansion module.

9. The information processing system of claim 1,
further comprising a second drive bay radiator module disposed in a second drive bay of the drive bays,
wherein the drive bay liquid connectors include a second set of drive bay liquid connectors fluidically connecting the second drive bay radiator module to the liquid cooling loop.

10. The information processing system of claim 1,
further comprising one or more pluggable storage drives installed in one or more of the drive bays.

11. A drive-bay radiator module, comprising:
a housing configured to be insertable into a drive bay, or a set of adjacent drive bays, of an information processing device, each drive bay being configured to receive a pluggable storage drive;
a radiator housed in the housing and comprising an inlet liquid connector, an outlet liquid connectors, a conduit extending from the inlet liquid connector to the outlet liquid connector, and fins thermally coupled with the conduit;
engagement features coupled to side walls of the housing, the engagement features being complementary to engagement features of the drive bays;
wherein the inlet liquid connector and the outlet liquid connector are configured to mate with drive bay liquid connectors in the drive bay, or the set of drive bays, of the information processing device on condition of the drive bay radiator module being installed in the drive bay or the set of drive bays.

12. The drive-bay radiator module of claim 11,
wherein the drive bay radiator module is configured to fit within one of the drive bays of the information processing device.

13. The drive-bay radiator module of claim 11,
wherein the drive bay radiator module is configured to spans the set of multiple drive bays.

14. The drive-bay radiator module of claim 11,
wherein the inlet liquid connector and the outlet liquid connector comprise quick disconnect (QD) fittings.

15. The drive-bay radiator module of claim 11,
further comprising electromagnetic interference (EMI) shield springs coupled to the housing.

16. A method of manufacturing an information processing system, comprising:
arranging a set of liquid connectors in a drive bay, or a set of drive bays, of a front drive cage of an information processing device, the set of liquid connectors being fluidically connected to a liquid cooling loop of the information processing device, the liquid cooling loop comprising a primary radiator and one or more cold plates disposed in a chassis of the information processing device;
inserting a drive bay radiator module into the drive bay, or the set of drive bays; and
fluidically connected liquid connectors of the drive bay radiator with the set of liquid connectors in the drive bay, or the set of drive bays.

17. The method of claim 16,
wherein inserting the drive bay radiator module into the drive bay, or the set of drive bays, comprises engaging engagement features of at least one of the drive bays with complementary engagement features of the radiator module.

18. The method of claim 17,
wherein the engagement features of the drive bays are configured to removably receive pluggable storage drives.

19. The method of claim 16,
wherein the set of liquid connectors are quick disconnect (QD) fittings and fluidically connecting the liquid connectors of the drive bay radiator with the set of liquid connectors in the drive bay, or the set of drive bays, comprises blind mating the liquid connectors of the drive bay radiator with the set of liquid connectors in the drive bay, or the set of drive bays.

20. The method of claim 16, further comprising:
determining an amount of supplemental cooling needed by the system in excess of that which the primary radiator is capable of providing;
determining how many drive bay radiator modules will be needed to provide the determined amount of supplemental cooling; and
installing the determined number of drive bay radiator modules in drive bays of the front drive cage and fluidically connecting the drive bay radiator modules to the liquid cooling loop.
